(19) United States
(12) Patent Application Publication
(10) Pub. No.: US 2005/0253129 A1
(43) Pub. Date: Nov. 17, 2005

(54) Light emitting diode with enhanced luminance and method for manufacturing the same

(76) Inventors: Tzong-Liang Tsai, Hsinchu (TW); Chih-Sung Chang, Hsinchu (TW); Wei-Chih Wen, Hsinchu (TW); Tzer-Perng Chen, Hsinchu (TW)

Correspondence Address: INGRASSIA FISHER & LORENZ, P.C., 7150 E. CAMELBACK, STE. 325, SCOTTSDALE, AZ, 85251, US

(21) Appl. No.: 10/949,456

(22) Filed: Sep. 23, 2004

(30) Foreign Application Priority Data
May 13, 2004 (TW) 93113437

(51) Int. Cl. H01L 29/06

(52) U.S. Cl. 257/13

(57) ABSTRACT

A light emitting diode with enhanced luminance and a method for manufacturing the light emitting diode are provided. The light emitting diode includes a substrate, a passivation layer including a material selected from a group consisting of a metal alloy, a metal oxide, a metal nitride, organic materials, inorganic materials and a combination thereof, a reflection layer, a first semiconductor layer, a multi-layer quantum well structure and a second semiconductor layer. The substrate possesses excellent electric/thermal conductivities.

### CROSS REFERENCE TO RELATED APPLICATIONS

This application claims priority to Taiwan Patent Application No. 093113437 entitled “Semiconductor Element with Enhanced Brightness and Method for manufacturing the Same”, filed on May 13, 2004, which is incorporated herein by reference and assigned to the assignee herein.

### FIELD OF INVENTION

The present invention generally relates to a semiconductor device and a method for manufacturing the same and, more particularly, to a light emitting diode with enhanced luminance and a method for manufacturing the same.

### BACKGROUND OF THE INVENTION

Light emitting diodes (LEDs), because of their unique structure and character of emitting lights, are different from those conventional light sources, and are more applicable to different industrial fields. Examples of LED applications are optical display devices, communication devices, and even lamp devices. However, to improve the luminance of LEDs is a continuous development. The luminance of LED is not unlimitedly increased as the current increases, but limited to the saturation current of the device.

The device size and heat dissipation ability are two important factors in the development of LEDs. For a given substrate area, smaller device size means that more devices are available, and the total luminance is accordingly increased. Moreover, LEDs with excellent heat dissipation have longer operation lifetime and are suitable for applications of high current operation.

TW patent publication No. 00567618 (counterpart of U.S. publication No. 2004/0104393), entitled “Light Emitting Diode Having an Adhesive layer and a Reflective Layer and Manufacturing Method Thereof”, discloses a light emitting diode having a transparent adhesive layer to adhere an LED stack and a substrate having a reflective metal layer together so that the light rays directed to the reflective metal layer can be reflected therefrom to improve the luminance of the light emitting diode.

TW patent No. 149911 (counterpart of U.S. Pat. No. 6,441,403), entitled “Semiconductor device with roughened surface increasing external quantum efficiency”, provides a semiconductor light emitting device having a roughened surface formed by controlling growth temperature, which is incorporated herein by reference and assigned to the assignee herein. For AlInGaN series light emitting devices, the luminance enhancement of the device is above 40%. However, the improvements of device size and the heat dissipation are not mentioned.

Therefore, there is a need to provide a semiconductor light emitting device with enhanced luminance and heat dissipation ability.

### SUMMARY OF THE INVENTION

One aspect of the present invention is to provide a semiconductor device; such as a light emitting diode, which has a smaller device size so that for a given substrate area, the number of devices is increased resulting in the improvement of total luminance.

Another aspect of the present invention is to provide a light emitting diode with improved heat dissipation ability so as to improve the operation lifetime of the device.

A further aspect of the present invention is to provide a light emitting diode, which is suitable for applications of high current operation.

In one embodiment, the present invention provides a semiconductor device, such as a light emitting diode, which includes a substrate, a passivation layer, a reflection layer, a first semiconductor layer, a multi-layer quantum well structure and a second semiconductor layer. The passivation layer is on the substrate and includes a material selected from a group consisting of alloy, oxide, nitride, and a combination thereof. The reflection layer is on the passivation layer and has a high reflectivity to an electromagnetic wave. The first semiconductor layer is on the reflection layer, and the multi-layer quantum well structure is on the first semiconductor layer. The second semiconductor layer is on the multi-layer quantum well structure.

Another further aspect of the present invention is to provide a method for manufacturing a light emitting diode. The method includes providing a first substrate, which is electric/thermal conductive. A first semiconductor layer is formed on the first substrate. A multi-layer quantum well structure is formed on the first semiconductor layer. A second semiconductor layer is formed on the multi-layer quantum well structure. A reflection layer is formed on the second semiconductor layer. The reflection layer has a high reflectivity to an electromagnetic wave. A passivation layer is formed on the reflection layer. The passivation layer includes a material selected from a group consisting of alloy, oxide, nitride, and a combination thereof. A second substrate is provided on the passivation layer. The second substrate has electric/thermal conductivities higher than those of the first substrate. Then, the first substrate is removed.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a structural diagram of a semiconductor device in accordance with a first embodiment of the present invention;

FIG. 2 illustrates a schematic view of arrangement of electrodes when a passivation layer is conductive in accordance with one embodiment of the present invention;

FIG. 3 illustrates a schematic view of arrangement of electrodes when a passivation layer is non-conductive in accordance with another embodiment of the present invention;

FIG. 4 illustrates a structural diagram of a semiconductor device in accordance with a second embodiment of the present invention;

FIGS. 5A-5C illustrate cross-sectional views of forming a light emitting diode in accordance with one embodiment of the present invention;

FIG. 6 illustrates a schematic view of arrangement of electrodes when a passivation layer is conductive in accordance with another embodiment of the present invention; and

FIG. 7 illustrates a schematic view of arrangement of electrodes when a passivation layer is non-conductive in accordance with another embodiment of the present invention.

### DETAILED DESCRIPTION OF THE INVENTION

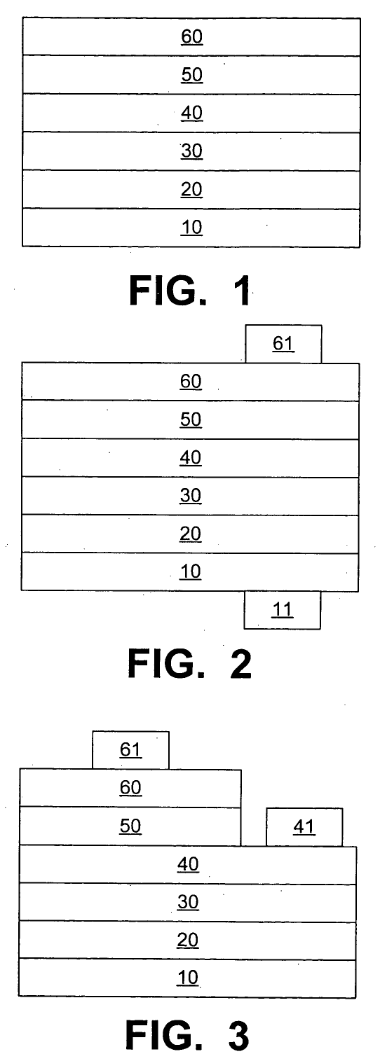

The present invention provides a semiconductor device with enhanced luminance, such as a light emitting diode, which has a smaller device size and excellent heat dissipation ability and is suitable for applications of high current operation. FIGS. 1-7 illustrate preferred embodiments of the present invention. It is noted that layers of the present invention can be grown by conventional processes, such as Metal Organic Chemical Vapor Deposition (MOCVD), Molecular Beam Epitaxy (MBE), Hydride Vapor Phase Epitaxy (HVPE), Liquid Phase Epitaxy, or evaporation. The layers can be bonded by eutectic bonding technology.

Referring to FIG. 1, in one embodiment of the present invention, a semiconductor device, such as a light emitting diode, includes a substrate 10, a passivation layer 20, a reflection layer 30, a first semiconductor layer 40, a multi-layer quantum well structure 50 and a second semiconductor layer 60.

The substrate 10 preferably has excellent electric/thermal conductivities higher than those of, for example, sapphire, lithium aluminum oxide (LAO), lithium gallium oxide (LGO), aluminum magnesium oxide (AlMgO), or the like. The substrate 10 can be a substrate having material of silicon, gallium nitride (GaN), SiC, or metal, such as copper or aluminum. The passivation layer 20 is on the substrate 10 and includes a material selected from a group consisting of alloy, oxide, nitride, and a combination thereof. The passivation layer 20 can be electric conductive or non-conductive depending on the design of device. Examples of conductive passivation layer include metals, such as Ni, W, Pt, or Ti, their alloys, and metal oxides, such as indium tin oxide (ITO), zinc oxide, titanium oxide, or titanium tungsten nitride. Examples of non-conductive passivation layer include organic materials, such as polyimide and bisbenzocyclobutadiene (BCB), and inorganic materials, such as silicon oxide and silicon nitrides. The reflection layer 30 is on the passivation layer 20. The reflection layer 30 having a high reflectivity to an electromagnetic wave can be made of silver (Ag), aluminum (Al), rhodium (Rh) and gold (Au). The electromagnetic wave is preferably in the infrared range, the visible light range or the ultra violet range. The reflectivity is preferably more than 90%. The layer positioned above the reflection layer 30, such as the first semiconductor layer 40, the multi-layer quantum well structure 50, or the second semiconductor layer 60, can include any suitable semiconductor material, preferably III-V compound semiconductor, such as Al_{y}GaₓIn_{1-x-y}N (0≦x≦1, 0≦y≦1, and 0≦x+y≦1) and is selectively doped to be P/N type as appropriate.

A GaN buffer layer is generally firstly formed on a base substrate. Then, the second semiconductor layer 60, the multi-layer quantum well structure 50, the first semiconductor layer 40, the reflection layer 30, and the passivation layer are sequentially formed on the GaN buffer layer. The substrate 10 is provided on the passivation layer 20, and the semiconductor structure is transferred onto the substrate 10 after the removal of the base substrate.

The light emitting diode further includes a first electrode and a second electrode. When the passivation layer 20 is electric conductive, the two electrodes can be disposed on opposite sides or on the same side with respect to the light emitting diode, preferably on opposite sides. As shown in FIG. 2, the first electrode 11 and the second electrode 61 are preferably on opposite sides with respect to the light emitting diode. For example, the first electrode 11 is on the substrate 10, and the second electrode 61 is on the second semiconductor layer 60. In such a configuration, the light emitting diode has a smaller size, and therefore, more devices can be fabricated in a given substrate area. As a result, the total luminance is improved.

Referring to FIG. 3, in an alternative embodiment, the light emitting diode includes a first electrode 41 and a second electrode 61 preferably on a same side with respect to the light emitting diode when the passivation layer 20 is electric non-conductive. In this case, the first electrode 41 is on the first semiconductor layer 40, and the second electrode is on the second semiconductor layer 60. It is noted that the first electrode 41 and the second electrode 61 can optionally be on opposite sides with respect to the light emitting diode. In this case, a channel for conduction is required.

Furthermore, a transparent conductive layer 70 is interposed between the reflection layer 30 and the first semiconductor layer 40 so as to improve the light emitting efficiency. The transparent conductive layer 70 having a relative small thickness can be metal or alloy of, for example, silver or nickel/gold, oxides, such as ITO, zinc oxide, nickel oxide, indium oxide, tin oxide or antimony oxide, or nitrides, such as titanium nitride or titanium tungsten nitride.

Moreover, an adhesion layer 80 can be interposed between the substrate 10 and the passivation layer 20 so as to ensure the adhesion of hetero-materials of the substrate 10 and the passivation layer 20. The adhesion layer 80 is selected from a group consisting a layer of silver paste, Au/Sn, In/Au and In/Pd. The adhesion layer 80 can also be an organic layer, such as polyimide or BCB.

For improvement of the light emitting efficiency, the surface of the light emitting diode can be roughened by etch or sand-blast processes. U.S. Pat. No. 6,441,403, entitled “Semiconductor Device with Roughened Surface Increasing External Quantum Efficiency”, discloses that the roughened surface reduces the overall reflection so as to increase the external quantum efficiency, which is incorporated herein by reference and assigned to the assignee herein.

Furthermore, the light emitting diode can be treated with energy wave after the base substrate is removed so as to improve device reliability and conductivity. The energy wave can be an acoustic wave, a microwave, or an excimer laser. The energy wave treatment is a low temperature process. Therefore, the microwave energy absorbed by the device does not cause high temperature, which is likely to damage the reflection layer, the metal layer, the transparent conductive layer, or the device itself. The low temperature energy wave treatment is a process having the advantages of restoring surface defects of the device and activating the conductivity of P/N semiconductor layer without damaging the device. It is noted that the energy wave treatment enables the movement of atomics in the surface so as to restore the crystallization of the surface and enhance the semiconductor property.

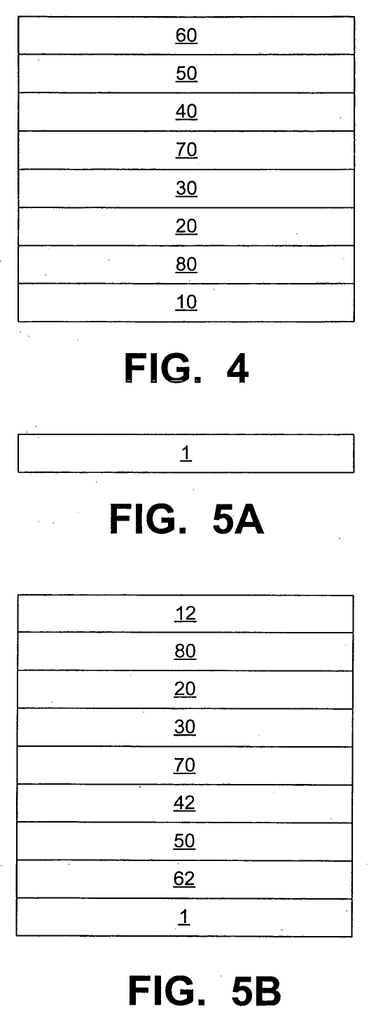

Referring to FIGS. 5A to 5C, in another embodiment, the present invention provides a method of forming a light emitting diode. The method includes providing a first substrate 1, which is electric/thermal conductive. A first semiconductor layer 62 is formed on the first substrate 1. A multi-layer quantum well structure 50 is then formed on the first semiconductor layer 62. A second semiconductor layer 42 is formed on the multi-layer quantum well structure 50. Next, a reflection layer 30 is formed on the second semiconductor layer 42. The reflection layer 30 has a high reflectivity to an electromagnetic wave. A passivation layer 20 is then formed on the reflection layer 30. The passivation layer 20 includes a material selected from a group consisting of alloy, oxide, nitride, and a combination thereof Then, a second substrate 12 is provided on the passivation layer 20. The second substrate 12 has electric/thermal conductivities higher than those of the first substrate 10. The first substrate 1 is then removed so that layers originally formed thereon are transferred onto the second substrate 12.

The first substrate 1 (i.e. the base substrate), the second substrate 12 (i.e. the substrate 10 of FIG. 1), the passivation layer 20, the reflection layer 30, the first semiconductor layer 62, the multi-layer quantum well structure 50 and the first semiconductor layer 42 are similar to those described in FIG. 1, and not elaborated again.

The removal of the first substrate 1 can be achieved by physical or chemical polishing techniques, or by laser detaching techniques. The passivation layer 20 is served to protect the reflection layer 30 from being damaged in subsequent processes. Moreover, a buffer layer, such as GaN buffer layer, can be formed on the first substrate 1 prior to the formations of other semiconductor layers.

The method further includes a step of forming a transparent conductive layer 70 on the second semiconductor layer 42 before the reflection layer 30 is formed so that the light emitting efficiency can be improved. The method further includes a step of forming an adhesion layer 80 on the passivation layer 20 before the second substrate 12 is provided so that the mechanical strength between hetero-materials of the second substrate 12 and the passivation layer 20 can be enhanced.

Furthermore, after the removal of the first substrate 1, a step of treating the light emitting diode with energy wave is performed. The energy wave is preferably an acoustic wave, a microwave, or an excimer laser. The energy wave treatment enables the movement of atoms in the surface so as to restore the crystallization of the surface and enhance the semiconductor property.

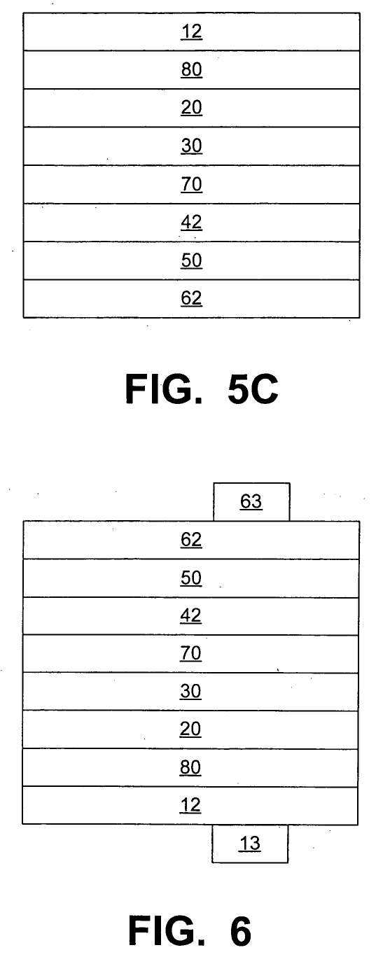

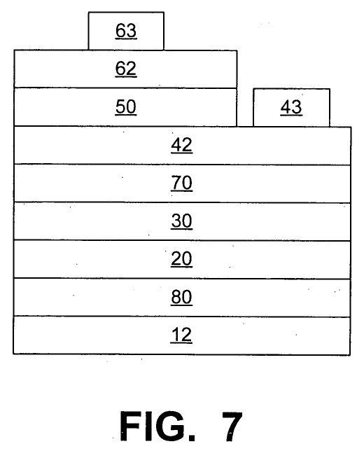

As shown in FIG. 6, the method further includes steps of forming a first electrode 63 and a second electrode 13. The first electrode 63 and the second electrode 13 are on opposite sides with respect to the light emitting diode when the passivation layer 20 is conductive. In this case, the first electrode 63 is on the first semiconductor layer 62, and the second electrode 43 is on the second substrate 12. When the passivation layer 20 is non-conductive, in an alternative embodiment, a first electrode 63 and a second electrode 43 is on a same side with respect to the light emitting diode. In this case, the first electrode 63 is on the first semiconductor layer 62, and the second electrode 43 is on the second semiconductor layer 42, as shown in FIG. 7.

### EXAMPLES OF METAL BONDING BLUE LIGHT EMITTING DIODE

### Example 1

An epitaxy-ready sapphire substrate is loaded into the OMVPE reactor chamber (not shown). The sapphire substrate is preheated for 10 minutes at about 1150 degrees centigrade. The temperature of the sapphire substrate is then lowered to about 500-600 degrees centigrade. At a temperature of about 520 degrees centigrade, a 25 nm thick GaN buffer layer is grown on the sapphire substrate. The temperature is again raised to about 1100 degrees centigrade and a 4 μm thick Si-doped GaN layer (N type doped) is grown on the buffer layer with a growth rate about 2 μm/hr. The sapphire substrate is then cooled down to about 820 degree centigrade. An InGaN/GaN multi-layer quantum well structure is grown on the top of the n-type Si-doped GaN layer. The multi-layer quantum well structure serves as a light emitting active layer. The temperature is then increased to about 1100 degrees centigrade, and a p-type Mg-doped GaN layer is grown on the InGaN/GaN multi-layer quantum well structure so that a light emitting diode epi-wafer is produced. A 2650 Å thick transparent conductive ITO layer as the passivation layer is evaporated on the surface of the device in nitrogen atmosphere at about 500° C. for 10 minutes. Then, a 2650 Å thick silver layer is evaporated serving as the reflection layer. It is noted that the passivation layer, i.e. the ITO layer, is about 3000 Å thick. A layer of gold of about 18000 Å serves as the adhesion layer. A silicon substrate serving as the second substrate with a 25000 Å thick indium layer facing the gold layer of the sapphire substrate is provided and placed in an oven at about 200° C. for 2 hours with an extra weight of 3 kg applied on the combined structure. Then, the combined structure is naturally cooled, for example, for about 1 hour or more to room temperature. It is noted that the second substrate can also be an aluminum oxide substrate, a SiC substrate or a GaAs substrate.

An energy density 400 mJ/cm², wave length 248 nm, pulse width 38 ns excimer laser is uniformly applied on the sapphire substrate, which is placed on a heating device to a raised temperature of about 60° C., so as to removed the sapphire substrate. The device dimension is a square in 300 μm times 300 μm, which is defined by dry etching processes. Then, a layer of Ti/Al (600 Å/2000 Å thick) is formed on the n-type GaN layer, and a layer of Ti/Au (600 Å/2000 Å thick) is formed on the silicon substrate as ohmic contacts.

### Example 2

After the formation of the epi-wafer as illustrated in Embodiment 1, a nickel layer having a thickness less than about 50 Å is evaporated on the surface in oxygen atmosphere at about 60° C. for 10 minutes. Then, a 2000 Å thick aluminum layer as the reflection layer, a 2000 Å TiWN passivation layer and a 18000 Å thick gold adhesion layer are sequentially formed. A silicon substrate with a 25000 Å thick indium layer facing the gold layer of the sapphire substrate is provided and placed in an oven at about 200° C. for 2 hours with an extra weight of 3 kg applied on the combined structure. Then, the combined structure is naturally cooled, for example, for about 1 hour or more to room temperature.

An energy density 400 mJ/cm², wave length 248 nm, pulse width 38 ns excimer laser is uniformly applied on the sapphire substrate, which is placed on a heating device to a raised temperature of about 60° C., so as to removed the sapphire substrate. The device dimension is a square in 300 μm times 300 μm, which is defined by dry etching processes. Then, a layer of Ti/Al (600 Å/2000 Å thick) is formed on the n-type GaN layer, and a layer of Ti/Au (600 Å/2000 Å thick) is formed on the silicon substrate as ohmic contacts.

Although specific embodiments have been illustrated and described, it will be obvious to those skilled in the art that various modifications may be made without departing from what is intended to be limited solely by the appended claims.

1. A light emitting diode, comprising:
a substrate;
a passivation layer on said substrate, said passivation layer comprising a material selected from a group consisting of alloy, oxide, nitride, and a combination thereof;
a reflection layer on said passivation layer, said reflection layer having a high reflectivity to an electromagnetic wave;
a first semiconductor layer on said reflection layer;
a multi-layer quantum well structure on said first semiconductor layer; and
a second semiconductor layer on said multi-layer quantum well structure.

2. The light emitting diode of claim 1, further comprising a transparent conductive layer interposed between said reflection layer and said first semiconductor layer.

3. The light emitting diode of claim 1, further comprising an adhesion layer interposed between said substrate and said passivation layer.

4. The light emitting diode of claim 1, wherein said passivation layer is electric conductive.

5. The light emitting diode of claim 4, further comprising a-first electrode and a second electrode on opposite sides with respect to said light emitting diode, wherein said first electrode is on said substrate, and said second electrode is on said second semiconductor layer.

6. The light emitting diode of claim 1, further comprising a first electrode and a second electrode on a same side with respect to said light emitting diode, wherein said first electrode is on said first semiconductor layer, and said second electrode is on said second semiconductor layer.

7. A light emitting diode, comprising:
a substrate;
an adhesion layer on said substrate;
a passivation layer on said adhesion layer, said passivation layer comprising a material selected from a group consisting of alloy, oxide, nitride, and a combination thereof;
a reflection layer on said passivation layer, said reflection layer having a high reflectivity to an electromagnetic wave;
a transparent conductive layer on said reflection layer;
a first semiconductor layer on said transparent conductive layer;
a multi-layer quantum well structure on said first semiconductor layer; and
a second semiconductor layer on said multi-layer quantum well structure.

8. The light emitting diode of claim 7, wherein said passivation layer is electric conductive.

9. The light emitting diode of claim 8, farther comprising a first electrode and a second electrode on opposite sides with respect to said light emitting diode, wherein said first electrode is on said substrate, and said second electrode is on said second semiconductor layer.

10. The light emitting diode of claim 7, further comprising a first electrode and a second electrode on a same side with respect to said light emitting diode, wherein said first electrode is on said first semiconductor layer, and said second electrode is on said second semiconductor layer.

11. A method of forming a light emitting diode, comprising:
providing a first substrate;
forming a first semiconductor layer on said first substrate;
forming a multi-layer quantum well structure on said first semiconductor layer;
forming a second semiconductor layer on said multi-layer quantum well structure;
forming a reflection layer on said second semiconductor layer, said reflection layer having a high reflectivity to an electromagnetic wave;
forming a passivation layer on said reflection layer, said passivation layer comprising a material selected from a group consisting of alloy, oxide, nitride, and a combination thereof,
providing a second substrate on said passivation layer, said second substrate having electric/thermal conductivities higher than those of said first substrate; and
removing said first substrate.

12. The method of claim 11, further comprising a step of forming a transparent conductive layer on said second semiconductor layer before said reflection layer is formed.

13. The method of claim 11, further comprising a step of forming an adhesion layer on said passivation layer before said second substrate is provided.

14. The method of claim 11, wherein said passivation layer is electric non-conductive.

15. The method of claim 11, further comprising forming a first electrode and a second electrode on opposite sides with respect to said light emitting diode, wherein said first electrode is on said first semiconductor layer, and said second electrode is on said second substrate.

16. The method of claim. 14, further comprising forming a first electrode and a second electrode on a same side with respect to said light emitting diode, wherein said first electrode is on said first semiconductor layer, and said second electrode is on said second semiconductor layer.

17. The method of claim 11, further comprising performing a microwave treatment on said light emitting diode.

18. A method of forming a light emitting diode, comprising:
providing a first substrate;
forming a first semiconductor layer on said first substrate;
forming a multi-layer quantum well structure on said first semiconductor layer;
forming a second semiconductor layer on said multi-layer quantum well structure;
forming a transparent conductive layer on said second semiconductor layer;
forming a reflection layer on said transparent conductive layer, said reflection forming a passivation layer on said reflection layer, said passivation layer comprising a material selected from a group consisting of alloy, oxide, nitride, and a combination thereof;
forming an adhesion layer on said passivation layer;
providing a second substrate on said adhesion layer, said second substrate having electric/thermal conductivities higher than those of said first substrate; and
removing said first substrate.

19. The method of claim 18, wherein said passivation layer is electric non-conductive.

20. The method of claim 18, further comprising forming a first electrode and a second electrode on opposite sides with respect to said light emitting diode, wherein said first electrode is on said first semiconductor layer, and said second electrode is on said second substrate.

21. The method of claim 19, further comprising forming a first electrode and a second electrode on a same side with respect to said light emitting diode, wherein said first electrode is on said first semiconductor layer, and said second electrode is on said second semiconductor layer.

22. The method of claim 18 further comprising performing a microwave treatment on said light emitting diode.
